(19) United States
(12) Patent Application Publication
(10) Pub. No.: US 2012/0139573 A1
(43) Pub. Date: Jun. 7, 2012

(54) TEST BRACKET FOR CIRCUIT BOARD

(75) Inventors: HUI LI, Shenzhen City (CN); FA-SHENG HUANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/967,069

(22) Filed: Dec. 14, 2010

(30) Foreign Application Priority Data
Dec. 4, 2010 (CN) 201010573493.X

(51) Int. Cl. G01R 1/04

(52) U.S. Cl. 324/756.07

(57) ABSTRACT

A test bracket for testing a circuit board includes a base, two connection pieces, and a supporting member for supporting the circuit board. The base includes a board and two posts extending up from the board. The supporting member is pivotably installed between the posts. First ends of the connection pieces are respectively slidably connected to the posts, and second ends of the connection pieces opposite to the first ends are respectively pivotably connected to opposite sides of the supporting member.

### BACKGROUND

1. Technical Field

The present disclosure relates to a test bracket for testing circuit boards.

2. Description of Related Art

Circuit boards of electronic devices need to be tested before shipment. Generally, a circuit board is put on an insulation board for testing one side of the circuit board. After that, the circuit board is turned over and put on the insulation board, so that the other side can be tested. However, when the circuit board is turned this way, elements of the circuit board may be damaged, and furthermore, this method is time consuming.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a test bracket for a circuit board.

FIG. 2 is an assembled, isometric view of the test bracket of FIG. 1, together with a circuit board.

FIG. 3 is an assembled, isometric view of the test bracket of FIG. 1.

FIG. 4 is a use state view of the test bracket of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

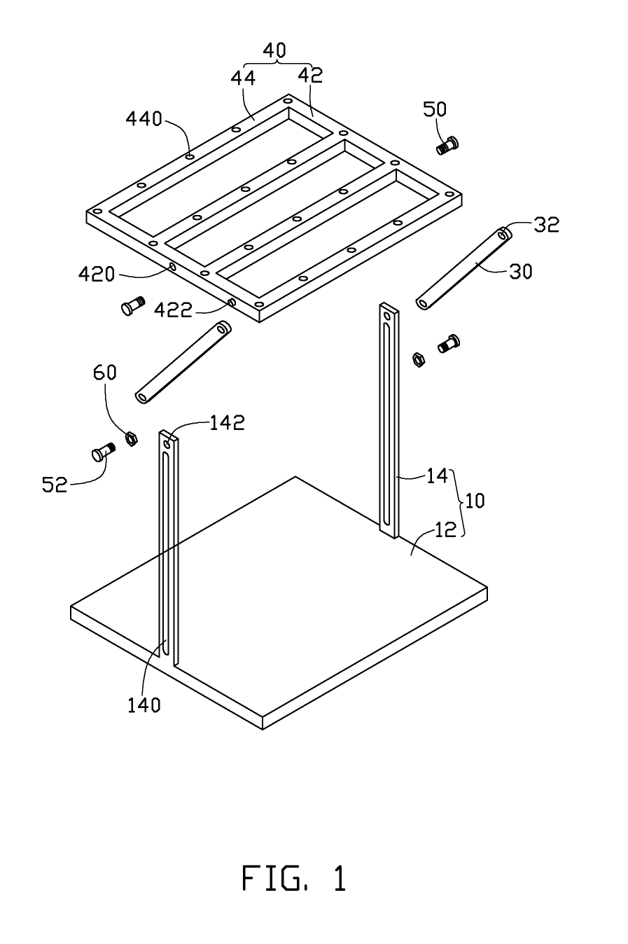

Referring to FIG. 1, an exemplary embodiment of a test bracket for a circuit board 70 includes a base 10, two connection pieces 30, and a supporting member 40.

The base 10 includes a substantially rectangular-shaped board 12 and two long posts 14 substantially perpendicularly extending up from opposite sides of the board 12. Each post 14 defines a longitudinal slot 140 extending through opposite sides of the post 14 from one end to near the other opposite end and perpendicular to the board 12. A through hole 142 is defined in an upper portion of each post 14 opposite to the board 12.

The connection pieces 30 are bar-shaped. Each connection piece 30 respectively defines two through holes 32 in opposite ends thereof.

The supporting member 40 is made of insulating material, such as wood or plastic. The supporting member 40 includes two parallel supporting posts 42 and a plurality of ribs 44 substantially perpendicularly connected between the supporting posts 42. A fixing hole 420 is defined in a center of each supporting post 42 opposite to the other supporting post 42. Two protrusions 422 extend from the supporting posts 42 respectively, at a same side of the corresponding fixing holes 420. A plurality of spaced fixing holes 440 is defined in a top of each rib 44.

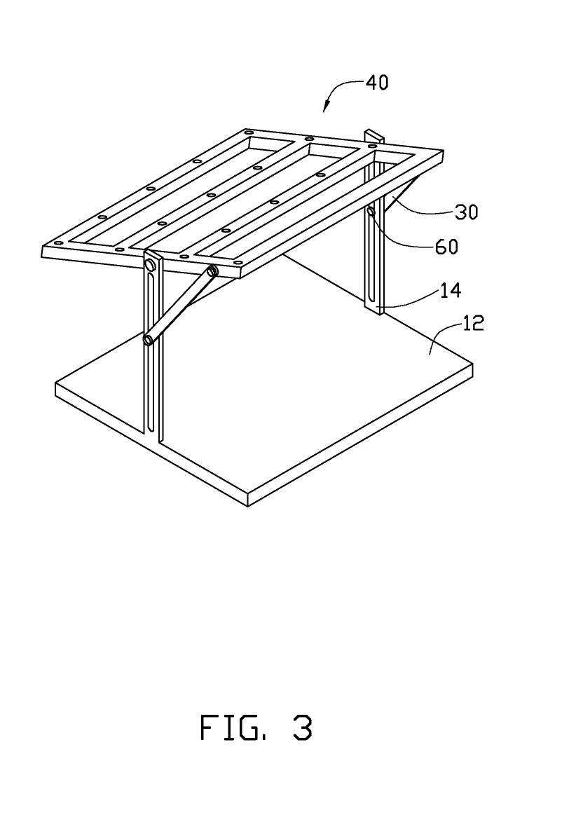

Referring to FIG. 3, in assembly, the supporting member 40 is located between the posts 14 of the base 10, with the fixing holes 420 of the supporting member 42 aligned with the corresponding through holes 142 of the posts 14. Two screws 50 pivotably extend through the through holes 142 of the posts 14 and engage in the corresponding fixing holes 420 of the supporting member 40. Therefore, the supporting member 40 is pivotably installed to the base 10.

The protrusions 422 of the supporting member 40 are pivotably engaged in the through holes 32 of corresponding ends of the connection pieces 30. Two screws 52 slidably extend through the through holes 32 of the other ends of the corresponding connection pieces 30 and the slots 140 of the corresponding posts 14, and then engage in two nuts 60. Therefore, the connection pieces 30 are slidably mounted to the corresponding posts 14.

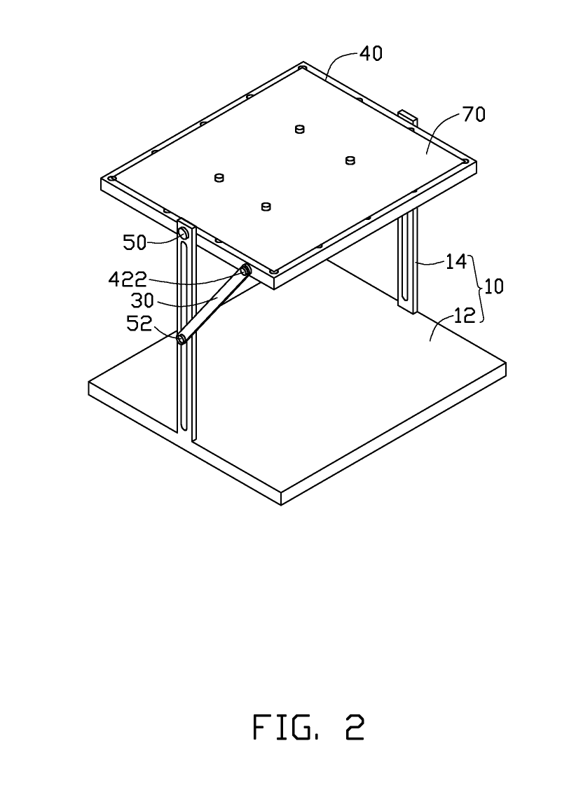

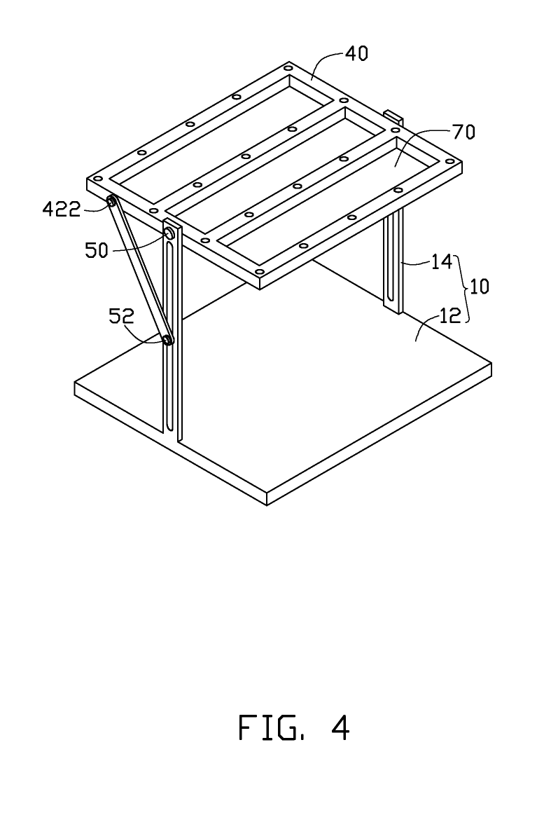

Referring to FIG. 2 and FIG. 4, in use, a plurality of screw extend through the circuit board 70, and engage in the fixing holes 440 of the supporting member 40 to fix the circuit board 70 to the test bracket. Therefore, a side of the circuit board 70 can be tested. The nuts 60 are loosened, the connection pieces 30 are moved along the slots 140 of the posts 14 to turn over the supporting member 40 with the circuit board 70. After that, the nuts 60 are retightened to fix the connection pieces 30. Therefore, the circuit board 70 can be turned easily and safely, and an opposite side of the circuit board 70 can be tested.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A test bracket for testing a circuit board, the test bracket comprising:
a base comprising a board and two posts substantially perpendicularly extending up from the board and spaced apart from each other;
two connection pieces, and
a supporting member to support the circuit board;
wherein the supporting member is pivotably installed between the two posts, first ends of the connection pieces are respectively slidably connected to the posts, and second ends of the connection pieces are respectively pivotably connected to opposite sides of the supporting member.

2. The test bracket of claim 1, wherein a through hole is define in each post, two fixing hole are defined in opposite sides of the supporting member, two screws respectively pivotably extend through the through holes of the posts and engage in the fixing holes of the supporting member.

3. The test bracket of claim 1, wherein a slot is longitudinally defined in each post, a first through hole is defined in the first end of each connection piece, a screw extends through the first through hole of the connection piece and the slot of the corresponding post, and engages with a nut.

4. The test bracket of claim 3, wherein a second through hole is defined in the second end of each connection piece, two protrusions extend from opposite sides of the supporting member and pivotably engage in the second through holes of the corresponding connection pieces.

5. The test bracket of claim 1, wherein the supporting member includes two parallel supporting posts and a plurality of ribs substantially perpendicularly connected between the supporting posts, a plurality of fixing holes is defined in the supporting posts and the ribs for fixing the circuit board.

6. The test bracket of claim 1, wherein the supporting member is made of insulating material.
